(19) United States
(12) Patent Application Publication
(10) Pub. No.: US 2011/0127153 A1
(43) Pub. Date: Jun. 2, 2011

(54) ILLUMINATABLE SWITCH

(76) Inventor: Claus Enoch, Koge (DK)

(21) Appl. No.: 13/002,278

(22) PCT Filed: Jul. 6, 2009
(86) PCT No.: PCT/EP09/58507

§ 371 Date: Feb. 8, 2011

Related U.S. Application Data
(60) Provisional application No. 61/078,663, filed on Jul. 7, 2008.

(30) Foreign Application Priority Data
Jul. 4, 2008 (EP) 08159733.8

(51) Int. Cl. H01H 13/14; H05K 3/30

(52) U.S. Cl. 200/520; 29/832

(57) ABSTRACT

An arrangement of an illuminatable electrical switch and one or more light emitting elements on a circuit board, the illuminatable electrical switch comprising: a switching device, an actuator with a waveguide which is adapted to allow visible light to be transmitted therethrough. The one or more light emitting elements are arranged with respect to the waveguide such light emitted by the light emitting elements, is transmitted through the waveguide whereby the light is visible from an outer surface of the actuator.

### FIELD OF THE INVENTION

The present invention relates to an arrangement of an illuminatable electrical switch and one or more light emitting elements on a circuit board. The light emitting elements are arranged on the circuit board such they may emit light into a waveguide of an actuator of the switch.

### BACKGROUND OF THE INVENTION

In today's electronic devices switches are a commonly used component. As the switches often are electrically connected to circuits defined on a circuit board such as a printed circuit board (PCB), the switches are frequently mounted on the circuit board itself.

Moreover, switches are in some cases adapted to be illuminated depending on their electrical state, e.g. the switch may be illuminated when the switch provides an electrical connection.

In relation to the manufacture of any electrical component, cost is an issue. Accordingly, it is an object of an embodiment of the present invention to provide a switch which is cheaper to manufacture.

Furthermore, it is in the interest of any manufacture to be able to design components such that they are versatile and such that the components allow the costumers using the components to configure the components at a late stage in their production. In the case of illuminatable switches, it is desirable to provide a switch which is not predesignated to emit a predetermined colour of light, but rather may be adapted to emit light in a colour at the choosing of the costumer. Accordingly, it is an object of an embodiment of the present invention to provide an illuminatable switch which is not predesignated to emit a predetermined colour of light and which a customer adapt to emit light at a colour of his choosing.

### DESCRIPTION OF THE INVENTION

In a FIRST aspect, the present invention relates to an arrangement of an illuminatable electrical switch and one or more light emitting elements on a circuit board, the illuminatable electrical switch comprising:
a switching device movable between a switched and a non-switched position, the switching device comprising one or more one conductor sets each of which comprises a first and a second conductor both of which are electrically accessible from an outer surface of the switching device and which
   when the switching device is positioned in the switched position are electrically connected, and
   when the switching device is positioned in the non-switched position are not electrically connected; and
an actuator with a waveguide which is adapted to allow visible light to be transmitted therethrough, the actuator being coupled to the switching device such that the switching device, by finger pressure, may be moved between the switched and the non-switched position by means of the actuator;
   wherein the one or more light emitting elements, on the circuit board, are arranged with respect to the waveguide such light emitted by the light emitting elements, is transmitted through the waveguide whereby the light is visible from an outer surface of the actuator.

Contrary to conventional switches, the light emitting element is not integrated into the switching device itself in the present invention. This provides the advantage that the colour of the light emitted by the switch is not determined on delivery of the switch. On the contrary, costumers using the switch of the present invention will mount the switch and the light emitting elements separately.

In one embodiment, both the illuminatable electrical switch and the light emitting elements are mounted on and supported by the circuit board. In one embodiment this means that both the electrical switch and the light emitting elements are exclusively supported by and mounted on the circuit board i.e. such that they are not concurrently supported in another way or by/via another means e.g. such that they are not in direct contact with any other means/objects.

In one embodiment, ‘supported by’ means that the light emitting element and/or illuminatable electrical switch is/are in direct contact with the circuit board i.e. not via another element. In one embodiment ‘supported by’ means that the conductors of the supported elements are supported by the circuit board.

In one embodiment, the light emitting elements and the switching device are arranged such with respect to each other that—once the light emitting element and the switching device are mounted to the circuit board—the light emitting elements may be unmounted/removed/detached from the circuit board while the switching device remains mounted on and supported by the circuit board.

This provides the advantage that if the light emitting element is damaged e.g. due to application of a too high voltage, the light emitting elements may be replaced without removing the switching device.

In another embodiment, the light emitting elements and the illuminatable electrical switch are arranged such with respect to each other that—once the light emitting element and the illuminatable electrical switch are mounted to the circuit board—the light emitting elements may be unmounted/removed/-detached from the circuit board while the illuminatable electrical switch remains mounted on and supported by the circuit board.

In one embodiment, the light emitting elements are arranged laterally relative to the switching device, i.e. lying away from the centre of the switching device.

In one embodiment, the arrangement comprises two light emitting elements arranged in the area of the switch, such as four, such as six, such as eight light emitting elements. By “in the area” is meant that the light emitting elements are arranged to emit light into the wave guide, such the light is visible in the waveguide from an outer surface of the electrical device.

In one embodiment, the light emitting elements are provided in zones each of which comprises at least two light emitting elements e.g. of different colour. In one embodiment, each zone comprises three light emitting elements in the colours red, green and blue. It will be appreciated that by providing the light emitting elements in red, green and blue, any colour may be defined by controlling the intensity of the three light emitting elements in the zone.

In one embodiment, the waveguide is shaped such that when the illuminatable switching device and the one or more light emitting elements are arranged on the circuit board, the one or more light emitting element(s) is/are positioned below/underneath the waveguide. By below may be meant that the light emitting element(s) is/are interposed between the circuit board and the actuator of the device

The light emitting elements may be provided in a circle around the switching device. Alternatively, the light emitting elements may define a square, e.g. such that a light emitting element is provided in each of the corners of the square.

In one embodiment, an optical fibre is interposed between the light emitting element and the waveguide, thus allowing the light emitting element to be positioned further away from the switching device.

In one embodiment, the one or more of the light emitting elements comprises an LED and/or an incandescent bulb.

The circuit board may be a printed circuit board. However, it will be appreciated that the switching device and the light emitting elements may in some embodiments by arranged on other surfaces, such as a surface which does not define a circuit. In the latter example, the switching device and the light emitting elements may be electrically connected to a circuit by means of a plurality of conductors such as wires, flex prints etc.

In order to allow the switching device to be moved between the switched and the non-switched position, the switching device may comprise an activating element adapted to engage the actuator. In one embodiment, the activating element is moved linearly/translationally into or out of the switching device when the switching device is moved between the switched and the non-switched position. In another embodiment, the activating element is rotated in order to be moved between the two positions. In yet another embodiment, the activating element is pivoted in order to be moved between the two positions.

The switching device may comprise means for retaining the activating element in either of the two positions such that finger pressure must be applied to the actuator in order to move the activating element from one position to the other. In one embodiment, the activating element is biased towards the switching position, and is adapted to return to the switched position upon removal of finger pressure from the actuator. In other embodiments, the switching device is adapted to be biased towards the non-switched position and is adapted to return to the non-switched position upon removal of finger pressure from the actuator.

The switching device comprises any number of conductor sets, such as two, such as four, such as six, such as eight. Each of the conductor sets comprises a first and a second conductor, which are electrically accessible form an outer surface of the device. The first and second conductors may define terminals on the outer surface of the device for electrically connecting the switch to an electrical circuit. The terminals may be suitable for surface mounting of the device (SMD) or for traditionally mounting of components (i.e. where the terminals extents through a printed circuit board). It will be appreciated that the number of terminals will correspond to the number of conductors. Accordingly, the switching device may comprise two, four, six, eight or ten terminals or an even large number of terminals.

Inside the device, one of the conductors in a set may be moveable into and out of contact with the other of the conductors in the set. Alternatively, a further electrically conducting element may be adapted to be moved into and out of electrical contact with both the first and the second conductor in a set.

The illuminatable device comprises an actuator comprising a waveguide. In the context of the present invention the term “waveguide” shall be understood as a material which conducts visible light. The waveguide may be made from any of the materials known in optical fibre technology such as glass.

The waveguide may be adapted to distribute the light transmitted into it. As an example the waveguide may be adapted to diffuse light such that the light is evenly distributed over an outer surface of the waveguide.

In one embodiment, the waveguide may be coloured such as white, green, red, blue etc. In one embodiment, the waveguide is transparent.

In one embodiment, the waveguide comprises two or more separate waveguides. The separate waveguides may be arranged such with respect to the light emitting elements that one light emitting element is arranged to emit light into one of the waveguides, and another light emitting element is arranged to emit light into the other waveguide. By providing more than one waveguide, at least two different colours of light may be visible from the outer surface of the actuator at the same time. As an example two waveguides may be adapted to transmit green and red light concurrently such that both colours of light are visible from an outer surface of the device, e.g. next to each other.

In one embodiment, the waveguide defines an upper surface of the actuator, which is visible to a user of the actuator. Moreover, the waveguide may define one or more lower surfaces through which the light emitting element(s) emit light which the waveguide conducts/transmits to the upper surface of the actuator.

In order to prevent the light transmitted/guided inside the waveguide from being visible at the lateral sides of the actuator, the lateral sides of the actuator may be adapted to prevent light from being transmitted therethrough. As an example the sides may comprise a reflecting material or a non-transparent coating. Alternatively, or as a supplement a non-transparent liner may be defined on the outer lateral surfaces of the device

In one embodiment, the actuator defines at least one reflector surface adapted to reflect light emitted by the one or more light emitting elements so as to distribute the light evenly in the waveguide. The reflecting surface(s) may be provided below the waveguide. In one embodiment, the reflecting surface(s) abut(s) at least a part of the lower surface of the waveguide. Alternatively, the reflecting surface(s) and the waveguide are spaced apart at a predetermined distance, such as 0.5-2 mm.

In one embodiment, the actuator is coupled to the switching device such that the switching device, by finger pressure, may be moved between the switched and the non-switched position by means of the actuator. As an example the waveguide and the actuator may be detachably attached to each other, e.g. by means of a snap lock.

The switch of the illuminatable switch of the present invention may be a keyboard switch, a rotary switch, a toggle switch, an on-off switches or any other known type of switch.

At least a part of the switch may be moulded. As an example the switching device may be moulded e.g. such that the conductors are moulded into the switch.

It will be appreciated that the switching device and/or the actuator may have any shape such as round or polygonal e.g. triangular or quadrangular. The width and/or length of the switching device may be in the range 3-50 mm. The height of the switching device may be in the range 2-15 mm. The width and/or length of the actuator may be in the range 3-50 mm. The height of the actuator may be in the range 5-20 mm.

In one embodiment, movement of the switching device into one of the switched or the non-switched position causes the one or more light emitting elements to emit light. In the same embodiment, movement of the switching device into the other one of the switched or non-switched position causes the one or more light emitting elements not to emit light. As an example the light emitting elements may emit light when the switching device is positioned in the switched position and may not emit light when the switching device is positioned in the non-switched position. In the latter embodiment light is emitted when the switching device is “on” and no light is emitted when the switching device is “off”.

In a SECOND aspect, the present invention relates to an illuminatable electrical switch for use in the arrangement according to the first aspect of the invention.

It will be appreciated that the illuminatable electrical switch according to the second aspect may comprise any combination of features and/or elements of the invention according to the first aspect, especially the illuminatable switch according to the first aspect.

In a THIRD aspect, the present invention relates to a method of mounting an illuminatable switching device according to the first aspect of the invention and one or more light emitting devices to a circuit board, the method comprising the steps of:
mounting the switching device on the circuit board,
mounting the one or more light emitting elements on the circuit board such that when the actuator is coupled to the switching device, the one ore more light emitting elements is/are positioned below the wave guide, and
coupling the actuator to the switching device.

Again, it will be appreciated that the illuminatable electrical switch according to the third aspect may comprise any combination of features and/or elements of the invention according to the first aspect, especially the illuminatable switch according to the first aspect. Moreover, the light emitting element(s) of the third aspect may comprise any combination of features and/elements of the light emitting elements of the first aspect.

### BRIEF DESCRIPTION OF THE FIGURES

The invention will now be described with reference to the figures in which:

FIGS. 1-4 disclose an isometric view of the arrangement according to the present invention,

FIGS. 5-8 disclose the actuator according to the present invention, and

FIGS. 9-11 disclose the process of assembling the arrangement of the present invention.

### DETAILED DESCRIPTION OF THE FIGURES

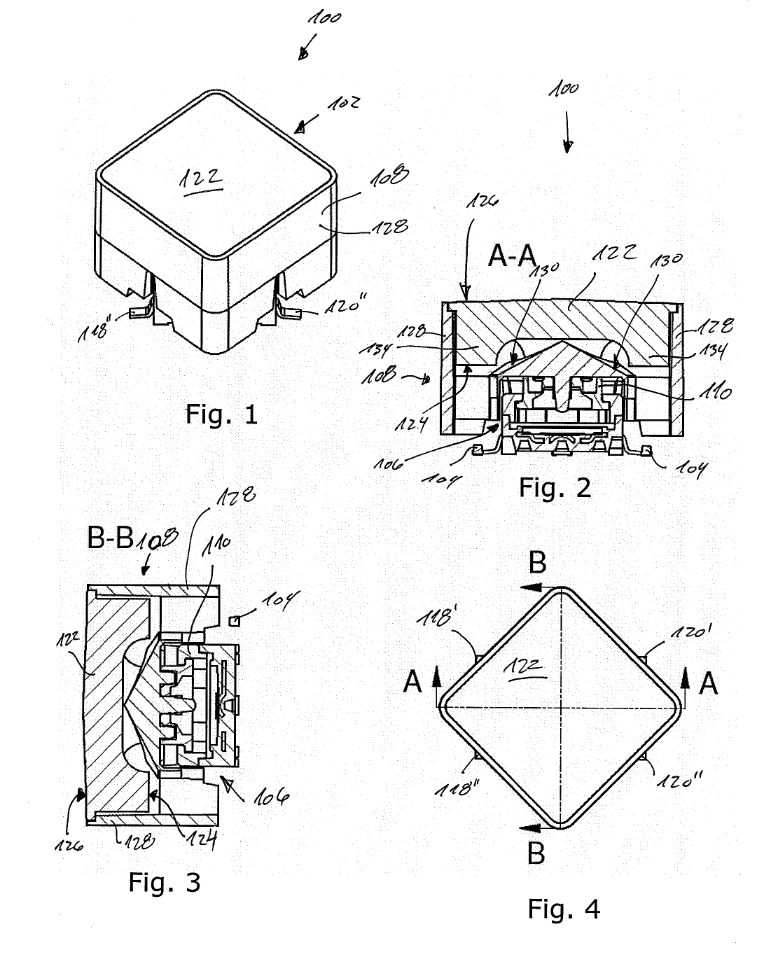

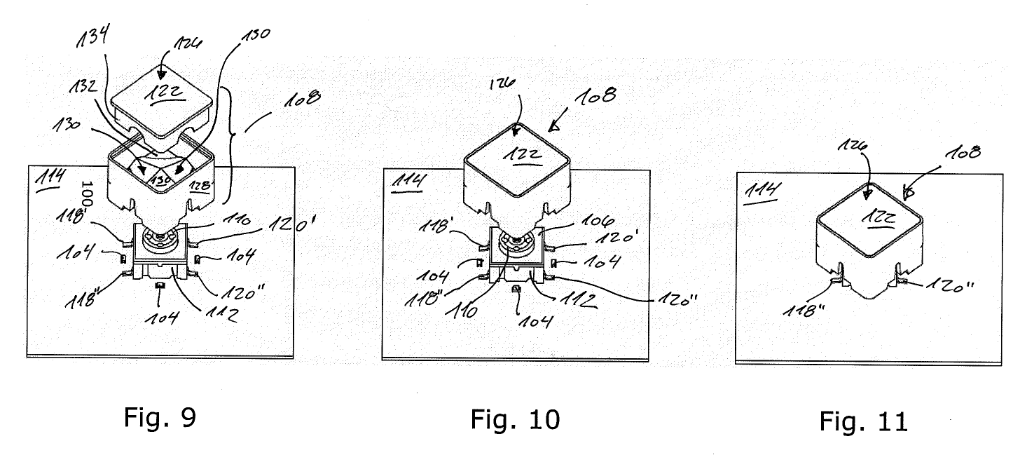

FIGS. 1-4 disclose an arrangement 100 of an illuminatable electrical switch 102 and four light emitting elements 104 (see also FIGS. 9 and 10). It will be appreciated that in other embodiments a different number of light emitting elements may be provided, such as three, such as five, such as seven, such as nine.

The illuminatable electrical switch 102 comprises a switching device 106 and an actuator 108. The switching device 106 comprises an activating element 110 which is adapted to be moved between a switched and a non-switched position. In the embodiment of FIGS. 1-4 and 9-11, said movement of the activating element 110 is a translational movement towards and away from a switch body 112 of the switching device and the circuit board 114 carrying the arrangement. The circuit board 114 may be seen in FIGS. 9-11.

Moreover, the switching device 106 comprises two sets of conductors 116′,116″ each of which comprises a first conductor 118′,118″ and a second conductor 120′,120″. In the embodiment of the figures, downwards movement of the activating element causes the switching device 106 to be positioned in the switched position whereby the conductors of the first set of conductors 116′ are electrically connected and whereby the conductors of the second set of conductors 116″ are electrically connected. Hence the first conductor 118′ is electrically connected to the second conductor 120′. Additionally the first conductor 118″ is electrically connected to the second conductor 120″.

In order to move the activating element into the non-switched position, the activating element may have to be moved slightly downwards in order to unlock the activating element from a switched locking position. Upon the slight downwards movement, the activating element will move upwards and into the non-switched position, in which the conductors of each of the conductor sets are not electrically connected. A biasing element (not shown) causes the switching element to be biased into the non-switched position once it has been unlocked from the switched position.

The actuator 108 comprises a waveguide 122 which is adapted to transmit the light emitted by the light emitting elements 104 from a lower surface 124 of the waveguide 122 to an upper surface 126 of the waveguide 122. In order to prevent light from being visible at the lateral sides of the actuator, a lining element 128 is provided, which contrary to the waveguide, is adapted to prevent light from begin transmitted therethrough. The actuator 108 defines four reflector surfaces 130 which are arranged such that light reflected by the lower surface 124 of the waveguide 122 is reflected back towards and into the lower surface 124 of the waveguide 122.

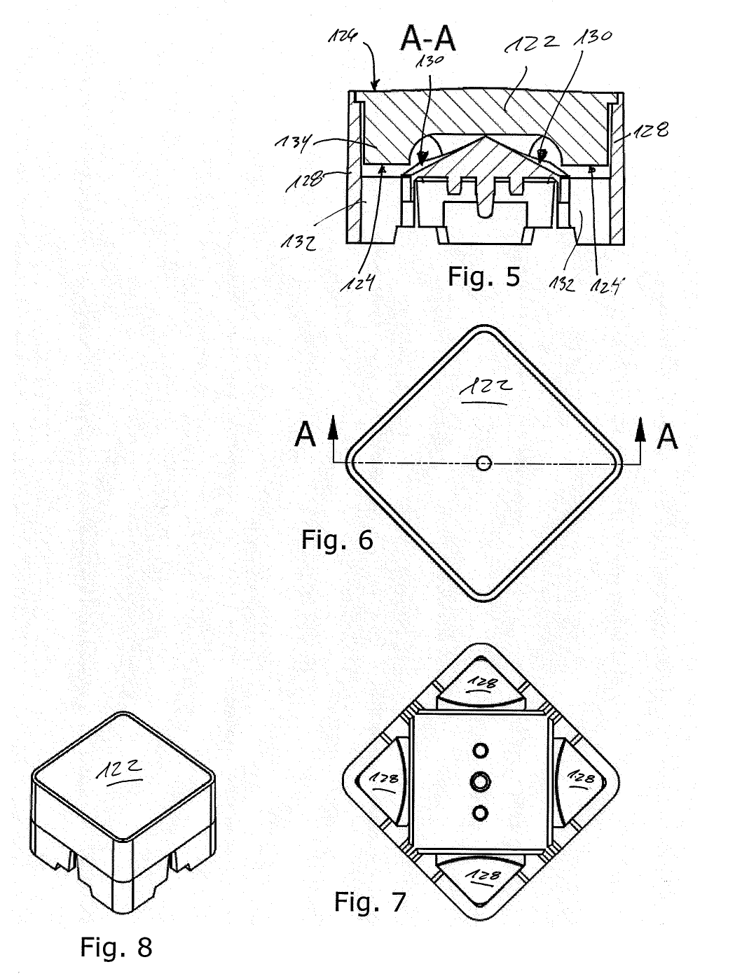

FIGS. 5-8 disclose different isometric and cross-sectional views of the actuator 108 and the waveguide 122. It may be seen that the waveguide 122 extends into cavities 132 of the lining element 128. Similarly the waveguide 122 comprises four legs 134 which when the waveguide 122 and the lining element 128 are assembled, extend into the cavities 132.

FIGS. 9-11 disclose the assembly of the arrangement 100. Initially, the switching device 106 and the light emitting elements 104 are mounted to the circuit board 114, e.g. by means of SMD technology. Subsequently, the lining element 128 is positioned on the switching device 106. In the embodiment of FIGS. 9-11 both the lining element 128 and the switching device 106 have a quadrangular cross section, and it may be seen in the figures that the two elements are rotated 45 degrees relative to each other, whereby the legs 134 are arranged above the light emitting elements 104. Finally, the waveguide 122 is assembled with the lining element 128. It will be appreciated that the lining element 128 and the waveguide 122 may be assembled prior to being assembled with the switching device 106.

1. An arrangement of an illuminatable electrical switch and one or more light emitting elements on a circuit board, the illuminatable electrical switch comprising:
a switching device movable between a switched and a non-switched position, the switching device comprising one or more one conductor sets each of which comprises a first and a second conductor, and which
when the switching device is positioned in the switched position are electrically connected, and
when the switching device is positioned in the non-switched position are not electrically connected; and
an actuator with a waveguide which is adapted to allow visible light to be transmitted therethrough, the actuator being coupled to the switching device such that the switching device, by finger pressure, may be moved between the switched and the non-switched position by means of the actuator;
wherein the one or more light emitting elements, on the circuit board, are arranged with respect to the waveguide such light emitted by the light emitting elements, is transmitted through the waveguide whereby the light is visible from an outer surface of the actuator; and
wherein the light emitting elements and the illuminatable electrical switch are arranged such with respect to each other that the light emitting elements may be removed from the circuit board while the illuminatable electrical switch remains mounted on and supported by the circuit board.

2. An arrangement according to claim 1, wherein both the illuminatable electrical switch and the light emitting elements are mounted on and supported by the circuit board.

3. An arrangement according to claim 1, wherein the light emitting elements and the switching device are arranged with respect to each other such that the light emitting elements may be unmounted/removed from the circuit board while the Switching device remains mounted on and supported by the circuit board.

4. An arrangement according to claim 1, wherein the light emitting elements are arranged laterally relative to the switching device.

5. An arrangement according to claim 1, wherein the movement of the switching device into one of the switched or the non-switched position causes the one or more light emitting elements to emit light, and wherein movement of the switching device into the other one of the switched or non-switched position causes the one or more light emitting elements not to emit light.

6. An arrangement according to claim 1, wherein the waveguide is shaped such that when the illuminatable switching device and the one or more light emitting elements are arranged on the circuit board, the one or more light emitting element(s) is/are positioned below the waveguide.

7. An arrangement according to claim 1, wherein the waveguide defines an upper surface of the actuator, and therein lateral sides of the actuator is adapted to prevent light from being transmitted therethrough.

8. An arrangement according to claim 1, wherein the actuator defines at least one reflector surface adapted to reflect light emitted by the one or more light emitting elements so as to distribute the light evenly in the waveguide.

9. An arrangement according to claim 1, wherein the waveguide is detachably attached to the actuator.

10. An illuminatable electrical switch for use in the arrangement according to claim 1.

11. A method of mounting an illuminatable switching device according to claim 1 and one or more light emitting devices to a circuit board, the method comprising the steps of:
mounting the switching device on the circuit board,
mounting the one or more light emitting elements on the circuit board such that when the actuator is coupled to the switching device, the one ore more light emitting elements is/are positioned below the wave guide, and
coupling the actuator to the switching device.
